(19) United States
(12) Patent Application Publication
(10) Pub. No.: US 2007/0069756 A1
(43) Pub. Date: Mar. 29, 2007

(54) Test fixture

(76) Inventors: David R. Ambler, Fort Collins, CO (US); Gary Joseph Kusluski, Windsor, CO (US); Eng-Hooi Teoh, Desa Ara (MY)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/239,512

(22) Filed: Sep. 29, 2005

(51) Int. Cl. G01R 31/26

(52) U.S. Cl. 324/765

(57) ABSTRACT

A test fixture is adapted to shield a device under test (DUT) from time dependent electromagnetic radiation.

### BACKGROUND

Wireless devices are used in a variety of settings and applications. After wireless devices are assembled, they are often tested by the manufacturer before shipment to the customer. Normally, the wireless devices are tested at the factory within close proximity of one another. Unfortunately, the wireless devices emit electromagnetic signals that can reduce the accuracy of the testing of nearby wireless devices. In addition, electromagnetic signals in the ambient environment of the factory can interfere with the accuracy of post-assembly testing.

In order to mitigate the interference from other wireless devices and the electromagnetic signals from the ambient environment, the wireless device under test (DUT) is often tested in a test fixture having a housing that provides electromagnetic shielding. For example, the DUT may be disposed in a housing made of a material that prevents radio-frequency (RF) or microwave frequency time-dependent signals from reaching the DUT. As can be appreciated, by mitigating the interference from other devices and the ambient environment, a greater testing accuracy of the DUT can be achieved.

The test fixture also includes electronics adapted to perform certain tests on the DUT. In order to provide the electronics in relatively close proximity to the DUT and for improved testing accuracy, the electronics are also provided in the housing of the test fixture. Often during testing, it is necessary to access the electronics, electrical connections to the electronics, pneumatic devices, or a combination thereof. In addition, it is often desirable to access the electrical components, connections and pneumatic devices without interrupting the testing. For example, it may be necessary to repair a connection or calibrate an electronic component during testing in order to preserve the behavior caused by the pneumatic or electronic interaction. Unfortunately, access to the electronic components, electrical connections and pneumatic devices requires the disconnection of electrical connections and thus the interruption of testing.

There is a need for a test fixture that overcomes at least the shortcomings described above.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1A is a conceptual view of a test fixture in accordance with an example embodiment.

FIG. 1B is a conceptual view of the housing in an open position in accordance with an example embodiment.

FIG. 2 is a conceptual view of a test fixture in accordance with an example embodiment.

FIG. 3 is a simplified schematic diagram of electrical and pneumatic components of a test fixture in accordance with an example embodiment.

### DETAILED DESCRIPTION

In the following detailed description, for purposes of explanation and not limitation, specific details are provided in order to provide a thorough understanding of example embodiments according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparati and methods may be omitted so as to not obscure the description of the example embodiments. Such methods and apparati are clearly within the scope of the present teachings.

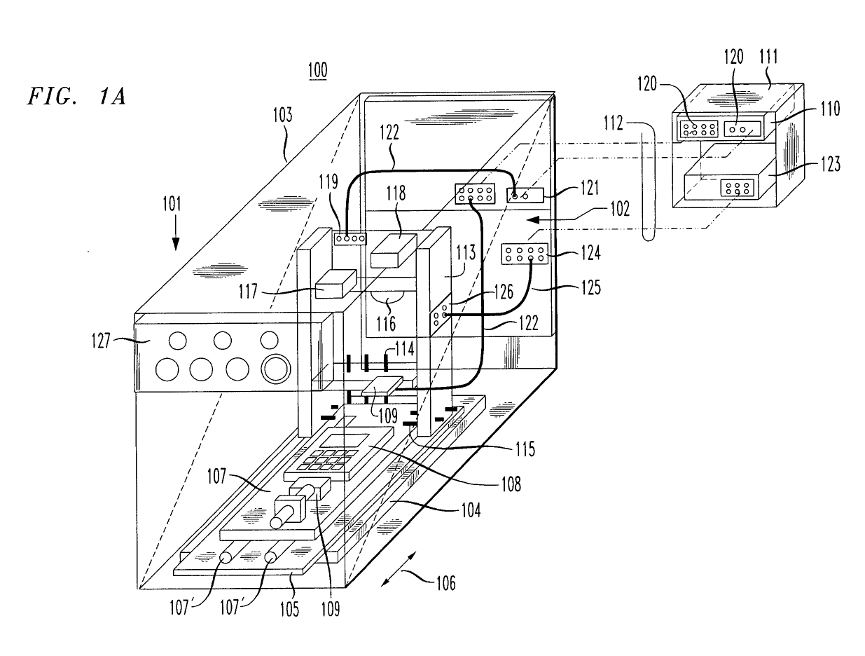

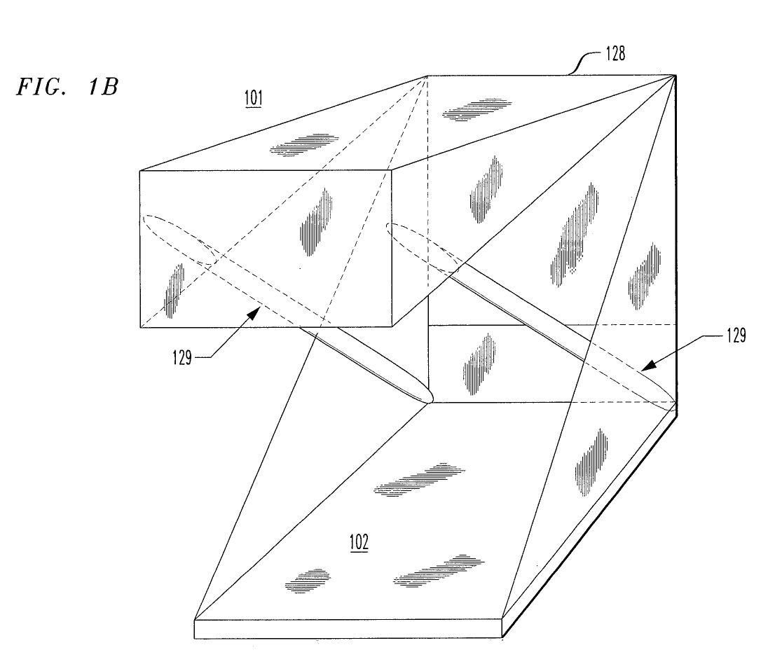

FIG. IA is a conceptual view of a test fixture 100 in accordance with an example embodiment. The test fixture 100 includes a housing 103 that includes a first portion 101 and a second portion 102. To facilitate the explanation of the function of the test fixture 100, the housing is shown as transparent. However, the housing 103 is normally not transparent. As described herein, when the first and second portions 101, 102 of the housing are closed as shown in FIG. 1A, certain frequency ranges of time varying electromagnetic radiation are substantially prevented from penetrating the housing. In a specific embodiment, the housing substantially blocks radio frequency (RF) signals over a specified frequency range from appreciably penetrating the housing. For example, the housing may be made of cast aluminum and may be lined with an rf absorbing material such as a ferrite material.

The test fixture 100 also includes a base 104 disposed in the housing. The base 104 may include electronics (not shown in FIG. 1A) useful in performing operational tests and may include electrical connections toward that end. A drawer 107 is disposed over the base 104 and with the top portion 101 in an open position; the drawer 107 is adapted to move inwardly and outwardly as shown by arrows 106 in FIG. 1A. Illustratively, the drawer 107 may be moved either manually or with a pneumatic drive. In a specific embodiment, the drawer 107 is guided into a recess (not shown) in the base. Additionally, or alternatively, the drawer 107 is guided via rails (not shown) on the base 104 or disposed in the recess.

An assembly 105 is disposed beneath the drawer 107, which is guided by pneumatic elements 107'. The drawer 107 holds a DUT 108 during testing. In a specific embodiment the DUT 108 is a wireless device such as a mobile telephone, personal digital assistant (PDA) or portable computer. In other embodiments, the DUT 108 may be another type of device susceptible to interference from time varying electromagnetic signals during operation.

The drawer 107 includes electrical connections 109 to the DUT 108 and may include a clamping mechanism (not shown) to maintain the DUT 108 in position. As described in further detail herein, the connections 109 provide power from an electronics module 110 disposed in an external hardware core hardware module 111. The external core hardware module 111 is adapted to connect to the rear of the test fixture 100 as indicated by reference numeral 112.

The test fixture 100 includes a mating structure 113 that is disposed over the base 104. The mating structure 113 includes keypad actuators 114 as well as side button actuators 115. The keypad actuators 114 are adapted to engage and depress pads on the keypad of the DUT 108. The side button actuators 115 are adapted to engage and depress pads located on the sides of the DUT 108 such as power keys. The actuators 114, 115 are useful in testing the functionality of the DUT 108. In addition to the actuators 114, 115, the mating structure 113 is adapted to include monitoring and testing components. These components include, but are not limited to, a camera 116, a light dependent resistor (LDR) 117 and a microphone and audio speaker 118. The test fixture also includes a plurality of electrical connections 119 that serve as a connection of power, or electrical signals, or both, between the camera 116, the LDR 117, the microphone and audio speakers 118 and the electronics module 110.

As noted, the housing 101 is made of a material that substantially blocks time dependent electromagnetic radiation from permeating the interior of the housing. Because of the concern that electromagnetic signals may interfere with the accuracy of the testing of the DUT 108, care is given to select materials for components within the housing that will not significantly contribute to this interference. As such, to the extent practical, components within the housing 101 comprise electrically insulating materials such as plastic or similar dielectric materials. For example, the base 104, the assembly 105, the drawer 107 and the mating structure 113 beneficially may be made of suitable plastic or similar dielectric materials.

External core hardware module 111 may be located on the outer portion of the housing 101. In a specific embodiment, the external core hardware module 111 is disposed on the rear surface of the lower portion 102 of the housing 103. In another specific embodiment, the core hardware module 111 is located within the housing 101. The electronics module 110 includes electrical circuitry and connections adapted to supply signals and power to the base 104, the assembly 105, the mating structure 113 and the DUT 108 via electrical connections 109 and 119. The electronics module 110 may include a core printed wiring board (not shown in FIG. 1A), input/output connections 120 for power and communications to and from the DUT 108 and power supplies (not shown in FIG. 1A) for the components of the test fixture 100 and DUT 108. The connections 120 connect with respective connections 121 on the housing 101. Connections between the connections 121 and the electrical connections 109 and 119 may be provided through suitable electrical cables 122. In order to avoid complexity in FIG. 1A, only a few cables 122 are shown.

The external core hardware module 111 may also include a pneumatics module 123 for supplying air to and controlling the valves of a pneumatic drive (not shown), pneumatic elements 107′ and actuators 114, 115. The pneumatic drive may be used to move the drawer 107 into and out of the housing 101 as needed. The pneumatic module 123 provides the pressure to engage the actuators 114, 115 that engage the keys and other control buttons of the DUT 108 during testing. The pneumatics module 123 also includes the electronics and components (e.g., valves) to selectively provide pneumatic pressure to the actuators 1 14, 115, elements 107′ and pneumatic drives of the test fixture.

The pneumatics module 123 includes an interface 124 that connects to hose(s) 125. The hoses carry air to receptacles 126 adapted to provide the air to the actuators 114, 115, elements 107′ and the pneumatic drive. Notably, only one of the hoses 125 is shown in the interest of simplicity of description. Clearly, multiple hoses may be used to provide the pneumatic pressure as needed during testing.

In another specific embodiment, the electronics and pneumatics of the external core hardware module 111 are located within the housing 101. For example, the electronics and pneumatics may be located beneath the base 104. Connections between the electronics and the base 104, the assembly 105, the mating structure 113 and the DUT 108 illustratively include printed circuit traces, cables and needed electrical connectors, which are known to one of ordinary skill in the art. In the embodiment having the printed wiring board beneath the base 104, circuit connections provide the connections between the printed wiring board and the base 104, and circuit connections and cables provide necessary electrical connections.

In addition to the electrical components described, the base 104, the assembly 105 and the mating structure 113 may each include circuitry and connections adapted to connect the various components thereof to one another as required and to the external hardware module 111. The circuitry and connections comprise known printed circuit board wiring traces, wiring busses, electrical connectors, cables, contacts and pneumatic components and thus are not described in significant detail. Moreover, the base 104 and the assembly 105 may comprise known printed circuit boards and printed wiring boards and needed electronics. Finally, an interface 127 is disposed on the front of the top portion as shown. The interface 127 includes control buttons and feedback lights. The interface may be used for a variety of control functions.

During testing, the drawer 107 moves the DUT 108 into the housing 101 so the DUT 108 is disposed under the mating structure 113. Notably, in FIG. 1A, the drawer 107 is not shown in its final position for testing. In the final position for testing, the drawer 107 locates the DUT 108 under the mating structure 113 so that the actuators 114, 115 and the camera 115, the LDR 116 and the speaker/microphone 117 are properly aligned with the DUT 108 so that testing may be carried out. In a specific embodiment, a stop (not shown) is included on the base 104 so that the DUT 108 is stopped in the proper position for testing. Alternatively, the movement of the drawer 107 may be terminated according to a pre-set positioning controlled by the pneumatic drive.

Once the DUT 108 is disposed under the mating structure 108, the actuators 114,115 are selectively moved to engage the various pads on the keypad and the sides of the DUT 108. The camera 116, the LDR 117 and the microphone and speaker 118 provide a monitoring and data gathering function. For example, the camera 116 may be used to monitor the quality of the display characters of the DUT 108; the microphone and speaker 118 may be useful in sending audio signals and receiving the audio feedback, respectively, from the DUT 108; and the LDR 117 may be useful in gathering data of the brightness of the display and keypad of the DUT 108 in various ambient lighting conditions.

Because the top portion 101 is closed, the DUT 108 is substantially not susceptible to interference from the time dependent electromagnetic signals of the ambient environment. In a specific embodiment where the testing is carried out in a manufacturing/assembly setting, the shielding function of the housing allows for accurate data gathering of the DUT 108 in operation.

During a test sequence, it may be necessary to perform maintenance. For example, maintenance may include troubleshooting a malfunctioning component, or repairing a component, or securing an electrical connection. In known test fixtures, this results in the disengagement of the electrical connections between the test fixture and the DUT and the termination of testing. However, this is readily carried out in the test fixture of the present embodiment by opening the top portion 101 of the housing and without terminating testing. This function is more clearly illustrated in FIG. 1B, where only the housing 101 is shown for clarity. As shown in FIG. 1B, the top portion 101 is attached to the bottom portion 102 by a hinge 128 disposed along the rear portion of the housing. The housing 101 also includes the arms 129 adapted to open and close the housing 101 by moving the top portion along the hinge 128. In a specific embodiment, the arms 129 are pneumatic and are controlled by components of the pneumatics module 123. Alternatively, the top portion 101 is opened manually.

When a test is desired in a shielded environment, the DUT 108 is loaded on the assembly 105 and necessary electrical and mechanical connections between the assembly 105 and the DUT 108 are made. Then the drawer 107 is driven into the housing by the pneumatic drive, or other similar devices, or manually. As described previously, the movement of the drawer 107 terminates when the DUT 108 is properly aligned relative to the mating structure 113 and components thereof for measurement/monitoring. Furthermore, any needed electrical connections between the mating structure 108 and the DUT 108, and the mating structure 113 and the assembly 105 are made manually, or automatically, or both. After connections and alignment procedures are completed, the top portion 101 is lowered by the arms 128 to engage the bottom portion 102 allowing for the housing 101 to properly shield the DUT 108 during the testing.

If during testing it becomes necessary to perform maintenance on connections to the DUT 108 or the components of the test fixture within the housing, the top portion 101 may be raised by activation of the arms 128 as shown in FIG. 1B. This allows for access to the DUT 108, the assembly 105, the DUT 108 and the mating structure 113 so that maintenance can be performed without termination of the test. Accordingly, the test fixture 100 of the example embodiment allows for maintenance or testing, or both, to be performed during a test sequence without terminating the testing sequence.

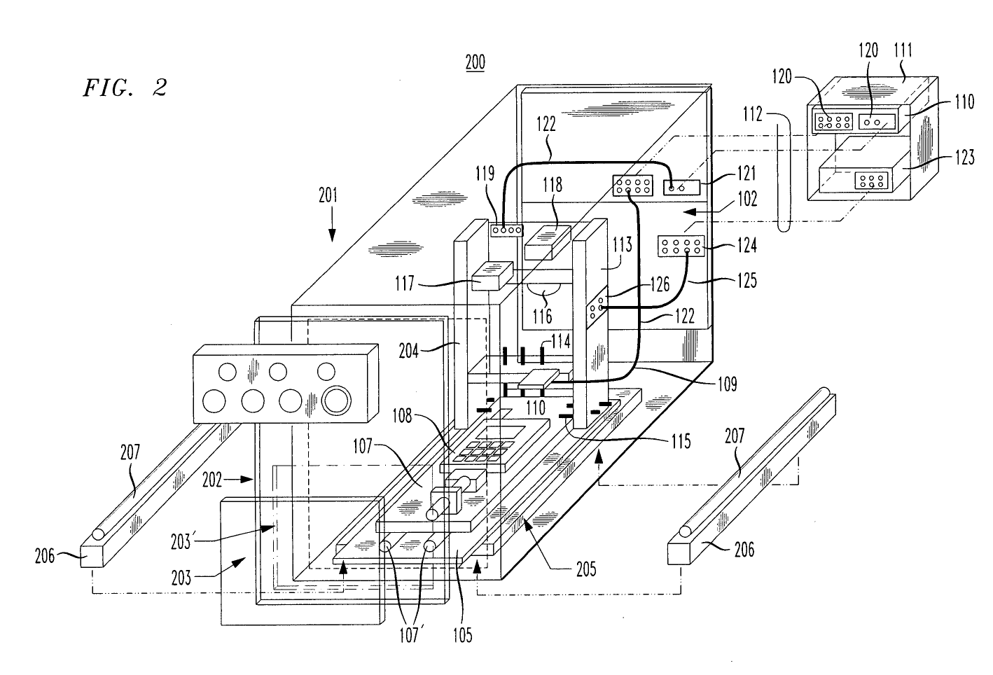

FIG. 2 is a conceptual view of a test fixture 200 according to another example embodiment. The test fixture 200 shares certain features with the test fixture 100 described in conjunction with FIG. 1A. The details of these features are not repeated so as to avoid obscuring the description of the present embodiment.

The test fixture 200 includes a housing 201 adapted to provide shielding from time dependent electromagnetic waves, such as RF waves. The housing includes a front panel 202 and a drawer panel 203. The front panel 202 is disposed over an aperture 204 on the housing 201 and the drawer panel 203 fits over an aperture 203′ in the front panel. When the front panel 202 is affixed over the aperture and the drawer panel 203 is closed over the aperture 203′ in the front panel 202, the front panel 202 and the drawer panel 203 provide shielding from time dependent electromagnetic radiation from the ambient. Again, in order to facilitate the description of the test fixture, the housing 201, the front panel 202 and the drawer panel 203 are shown in FIG. 2 as being transparent, although these components likely are not made of a transparent material. In a specific embodiment, the housing 201, the front panel 202 and the drawer panel 203 are made of one of the shielding materials disclosed previously in connection with FIG. 1A.

The drawer 107 including the DUT 108 is disposed over the assembly 105. The drawer 107 is disposed over a base 205. The mating structure 113 is also disposed over the base 205. In the present embodiment, the base 205 is adapted to slide along a rail 206 with the DUT 108 and the mating structure 113 remaining in alignment during movement. In a specific embodiment, the rail 206 includes a guide 207 that is adapted to engage a complementary cavity (not shown) in the lower portion of the base 205. As described herein, the base 205 with the assembly 105, the DUT 108 and the mating structure 113 may be removed from the housing 201 in order for maintenance to be performed during testing without terminating the testing.

In operation, the drawer 107 is moved out of the housing and the DUT 108 is loaded onto the assembly 105. The needed electrical and mechanical connections are made for operation of the DUT 108 during testing. Next, the drawer panel 203 is engaged to move the drawer 107 through an opening 203′ in the front panel 202 and the assembly 105 into the housing 201. As referenced previously, the movement of the drawer 107 may be carried out using pneumatic elements 107′ that engage the drawer 107 and moves the drawer 107 into and out of the housing 201. Alternatively, the drawer 107 may be moved manually or by other known mechanisms. The drawer 107 is then moved into position so that the assembly DUT 108 is aligned with the mating structure 113 and the actuators 114, 115 as described previously. After the alignment is complete, the drawer 107 is moved back into the housing, the drawer panel 203 close over the opening 203′ and testing in an RF shielded environment is carried out.

As noted in connection with the example embodiment of FIG. 1A, to the extent practical, components within the housing comprise substantially electrically insulating materials such as plastic. Accordingly, components such as the base 205, the rails 206 and the guides 207 may be made of materials that are substantially electrically insulating.

In the example embodiment, maintenance may be carried out on the test fixture without disrupting the testing procedure. In particular, if maintenance is needed, the drawer panel 203 and the front panel 202 are removed from the housing 201 and the base 205 is moved out of the housing 201. In this manner, the base 205 is moved along the rail 206 and out of the housing 201, providing access to the assembly 103, the DUT 108, the mating structure 113 and associated components. Because the assembly 103, the DUT 108 and the mating structure 113 remain in alignment with electrical connections in place, the testing may continue during the maintenance. As such, monitoring and testing by elements such as the camera 115, the LDR 116 and the microphone/speaker 117 continues, albeit not in a shielded environment while the maintenance is carried out. After the maintenance is completed, the base 205 is returned into the housing 200 and the drawer panel 203 and the front panel 202 are replaced, whereupon testing in an environment shielded from time varying electromagnetic waves continues.

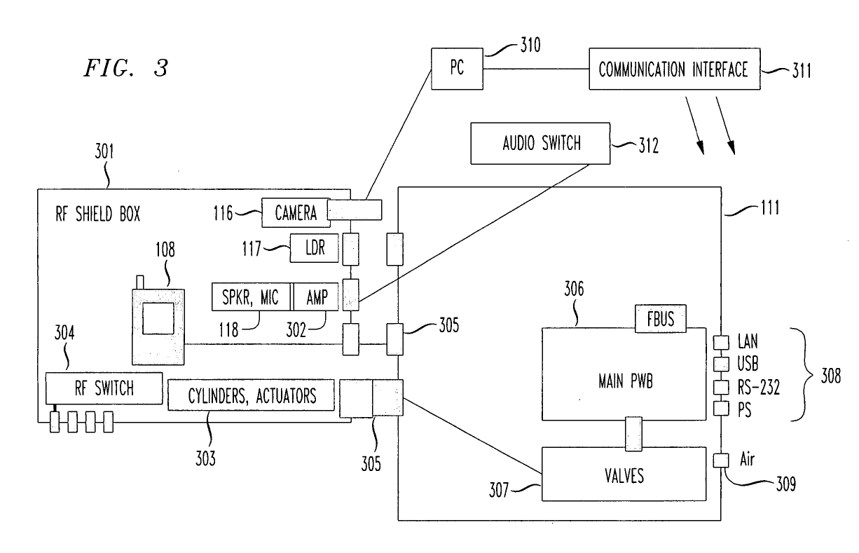

FIG. 3 is a simplified schematic diagram of a test fixture in accordance with an example embodiment. The test fixture includes an rf shield box 301, which may be a housing described in connection with the embodiments of FIGS. 1A-2. The DUT 108 is disposed in the box 301 and is aligned with the camera 116, the LDR 117 and the microphone/speaker 118. In this embodiment, the microphone/speaker 118 is connected to an amplifier 302.

The test fixture also includes pneumatic cylinders and actuators 303. The actuators may be the actuators 114, 115. The pneumatic cylinders are well known and are useful in movement of the drawer 104, the base 205 and the arms 128 in a manner described previously. The test fixture also includes an RF switch 304 useful in providing RF signals to the fixture as needed.

The external core electronics module 111 is connected to the rf shield box 301 via connections 305. These connections provide electrical and pneumatic feeds to the components in the rf shield box. For example, the connections may include the input/output connections 120, the connections 121, the air interface 124, the cables 122 and the hoses 125 described previously.

The test fixture also includes the main printed wiring board 306, which may be disposed in the electronics module 110 (not shown in FIG. 3) and pneumatic valves 307 that may be disposed in the pneumatics module 123 (not shown in FIG. 3). The printed wiring board 306 may be connected to monitoring and data gathering equipment (not shown) via various types of connections 307. Furthermore, air may be provided for the pneumatic elements by an air port 309.

During testing, the camera 116 provides images to a computer 310 that may be connected to a communications interface 311 such as a LAN hub 311. This is merely illustrative as other links may be used between the camera 116 and computer 310. In this manner, image data can be stored and shared during and after testing. An audio switch 312 is provided as an interface the microphone/speaker 118. The switch box 312 serves to select the speaker or the microphone of the DUT 108 depending on the selected test.

As can be appreciated, many of the components described in conjunction with the simplified schematic diagram of FIG. 3 are well within the purview of one of ordinary skill in the art. As such, details thereof are omitted to avoid obscuring the example embodiments.

In accordance with illustrative embodiments described, a test fixture is adapted to provide access to components for maintenance without terminating the testing of a DUT. One of ordinary skill in the art appreciates that many variations that are in accordance with the present teachings are possible and remain within the scope of the appended claims. These and other variations would become clear to one of ordinary skill in the art after inspection of the specification, drawings and claims herein. The invention therefore is not to be restricted except within the spirit and scope of the appended claims.

1. A test fixture, comprising:
a lower portion and an upper portion, wherein the upper portion is adapted to open;
an assembly adapted to receive a device under test (DUT) and disposed over a drawer, which is adapted to introduce the assembly into the lower portion and to remove the assembly from the upper portion;
a mating structure disposed in the lower portion and adapted to engage the DUT, wherein the mating structure and the assembly include components adapted to perform electrical testing of the DUT.

2. A test fixture as recited in claim 1, wherein the DUT is a wireless device.

3. A test fixture as recited in claim 1, wherein the lower portion and the upper portion comprise a housing of the test fixture and the lower portion and the upper portion include electromagnetic shielding material.

4. A test fixture as recited in claim 3, wherein the electromagnetic shielding material is a radio frequency (RF) shielding material.

5. A test fixtiire as recitcd in claim 3, wherein the electromagnetic shielding material is a microwave frequency shielding material.

6. A test fixture as recited in claim 1 wherein a hinge connects the upper portion to the lower portion.

7. A test fixture as recited in claim 6, wherein the upper portion and the lower portion are adapted to separate on the hinge and when separated, the electrical testing is not interrupted.

8. A test fixture as recited in claim 1, wherein the mating structure includes a plurality of actuators adapted to engage control pads on the DUT.

9. A test fixture as recited in claim 1, further comprising a camera adapted to record an output of a display from the DUT.

10. A test fixture as recited in claim 1, further comprising a speaker, which transmits audio signals to the DUT and a microphone, which receives audio signals from the DUT.

11. A test fixture, comprising:
a housing having a bottom and a front;
a base disposed over the bottom;
an assembly disposed over the base and adapted to receive a device under test (DUT);
a mating structure disposed over the base, wherein the mating structure and the drawer include electrical components and electrical connections adapted to perform electrical testing of the DUT, wherein the base is adapted to move the assembly and the mating structure from the housing without terminating the test.

12. A test fixture as recited in claim 11, further comprising a drawer adapted to move into and out of the housing, wherein the assembly is disposed over the drawer.

13. A test fixture as recited in claim 11, further comprising a panel disposed over the front, wherein the panel is adapted for removal from the front.

14. A test fixture as recited in claim 13, wherein upon the removal of the panel, the assembly, the mating structure and the drawer are adapted for removal from the housing.

15. A test fixture as recited in claim 11, wherein the housing includes electromagnetic shielding material.

16. A test fixture as recited in claim 15, wherein the electromagnetic shielding material is a radio frequency (RF) shielding material.

17. A test fixture as recited in claim 15, wherein the electromagnetic shielding material is a microwave frequency shielding material.

18. A test fixture as recited in claim 11, wherein the DUT is a wireless device.

19. A test fixture as recited in claim 11, further comprising a camera adapted to record an output of a display from the DUT,

20. A test fixture as recited in claim 1, further comprising a speaker, which transmits audio signals to the DUT and a microphone, which receives audio signals from the DUT.
